(19) United States
(12) Patent Application Publication
(10) Pub. No.: US 2010/0055617 A1
(43) Pub. Date: Mar. 4, 2010

(54) METHOD OF FORMING PATTERN IN SEMICONDUCTOR DEVICE

(76) Inventor: Jae-Young Choi, Yongin-si (KR)

Correspondence Address: SHERR & VAUGHN, PLLC, 620 HERNDON PARKWAY, SUITE 320, HERNDON, VA, 20170, US

(21) Appl. No.: 12/544,780

(22) Filed: Aug. 20, 2009

(30) Foreign Application Priority Data
Sep. 4, 2008 (KR) 10-2008-0087153

(51) Int. Cl. G03F 7/20; G03B 27/42

(52) U.S. Cl. 430/316; 355/53

(57) ABSTRACT

Disclosed is a method of forming a pattern in a semiconductor device. A first mask pattern to form dense lines and a second mask pattern to form spaces (parts where ends of lines are opposite to each other) are used when double patterning is applied to a photolithography process to form a line and space pattern on a semiconductor substrate. Therefore, when the line and space pattern is formed, a fine pattern may be formed without generating a bridge at parts where ends of lines are opposite to each other.

The present application claims priority under 35 U.S.C. 119 to Korean Patent Application No. 10-2008-0087153 (filed on Sep. 4, 2008), which is hereby incorporated by reference in its entirety.

### BACKGROUND

Pattern fineness is essential in manufacturing a highly-integrated semiconductor device. To integrate many devices in a narrow area, sizes of the respective devices must be reduced as far as possible. For that reason, a pitch, which is the sum of the widths of each of the patterns to be formed and an interval between the patterns, must be reduced.

Recently, as design rules for semiconductor devices have been rapidly reduced, there is a limit to formation of a pattern having a fine pitch due to a resolution limit in a photolithography process for forming a pattern required to implement the semiconductor device.

To overcome the resolution limit in the photolithography process, methods of forming a hard mask having a fine pitch using a double patterning process have been proposed. The double patterning process is a technique of forming a pattern using two photo masks. The above double patterning process facilitates formation of a pattern having a fine pitch using commercialized photolithography equipment.

FIGS. 1A to 1C are longitudinal-sectional views illustrating a related method of forming a fine pattern in a semiconductor device. As shown in FIG. 1A, a photoresist is coated over the upper surface of a semiconductor substrate 10, and is patterned using exposure and development processes, thereby forming a first photoresist pattern 12. Thereafter, the semiconductor substrate 10 is etched using the first photoresist pattern 12 as a mask.

As shown in FIG. 1B, the first photoresist pattern 12 is removed, and then a photoresist is coated again over the upper surface of the resultant entire structure. The photoresist is patterned using exposure and development processes, thereby forming a second photoresist pattern 14. Here, openings of the second photoresist pattern 14 do not overlie openings formed on the semiconductor substrate 10 using the first photoresist pattern 12.

As shown in FIG. 1C, the semiconductor substrate 10 is etched again using the second photoresist pattern 14 as a mask. Using this process, a fine pattern having a fine pitch may be formed.

The above-described general pattern forming method promotes ease in formation of the fine pattern through double patterning, but still has a limit in formation of a pattern having a fine pitch beyond the resolution limit. The reason is that it is difficult to control overlay accuracy when the exposure process is carried out using a photo mask. In particular, in the photolithography process of forming a line and space pattern (hereinafter, referred to as an “L/S pattern”) on a substrate, a mask error enhancement factor (MEEF) at a part where ends of lines are opposite to each other has a large value, and thus when the process is unstable, a bridge occurs.

### SUMMARY

Embodiments relate to a method of forming a pattern in a semiconductor device. In particular, Embodiments relate to a method of forming a pattern in a semiconductor device using a hard mask pattern having a fine pitch.

Embodiments relate to a method of forming a pattern in a semiconductor device, in which a first mask pattern to form lines and a second mask pattern to form spaces (parts where ends of the lines are opposite to each other) are used when double patterning is applied to a photolithography process to form a line and space pattern over a substrate. In this manner, a fine pattern may be formed, while generating no bridges at the parts where ends of the lines are opposite to each other.

Embodiments relate to a method of forming a pattern in a semiconductor device which includes forming a hard mask layer over an upper surface of a semiconductor substrate, forming a first photosensitive film pattern to form lines out of a line and space pattern over an upper surface of the hard mask layer, forming a first hard mask pattern by etching the hard mask layer using the first photosensitive film pattern as a mask, forming a second photosensitive film pattern to form spaces out of the line and space pattern over the upper surface of the resultant structure with the first hard mask pattern, forming a second hard mask pattern by etching the first hard mask pattern using the second photosensitive film pattern as a mask, and forming the line and space pattern by etching the semiconductor substrate using the second hard mask pattern as a mask.

The first photosensitive film pattern and the second photosensitive film pattern respectively may use photosensitive solutions of different types. The first photosensitive pattern may be formed corresponding to the lines, and use a positive-type photosensitive solution. The second photosensitive pattern may be formed corresponding to inverse shapes of the spaces, and use a negative-type photosensitive solution.

### DRAWINGS

FIGS. 1A to 1C are longitudinal-sectional views illustrating a related method of forming a pattern in a semiconductor device.

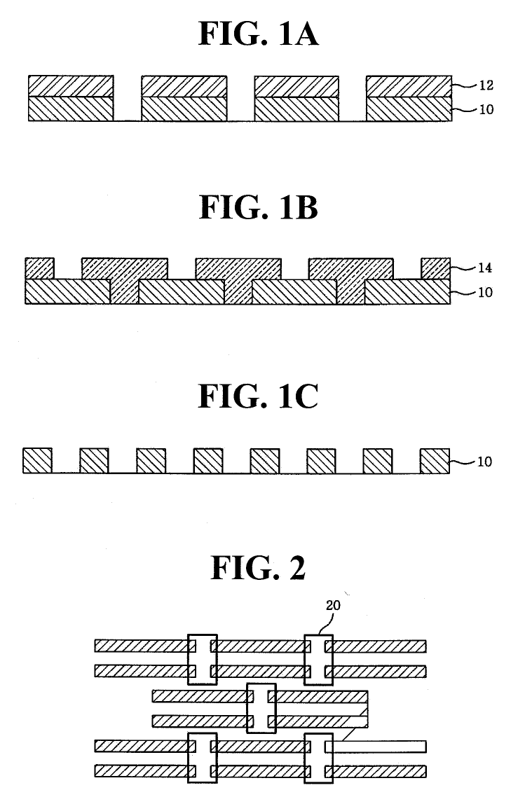

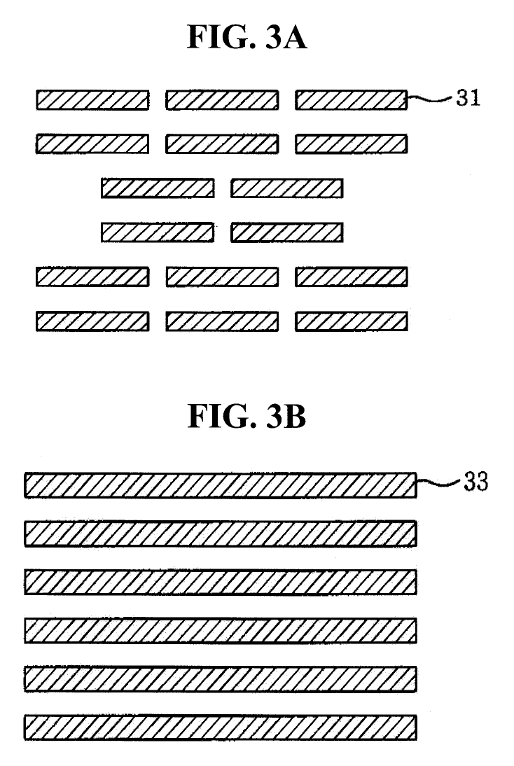

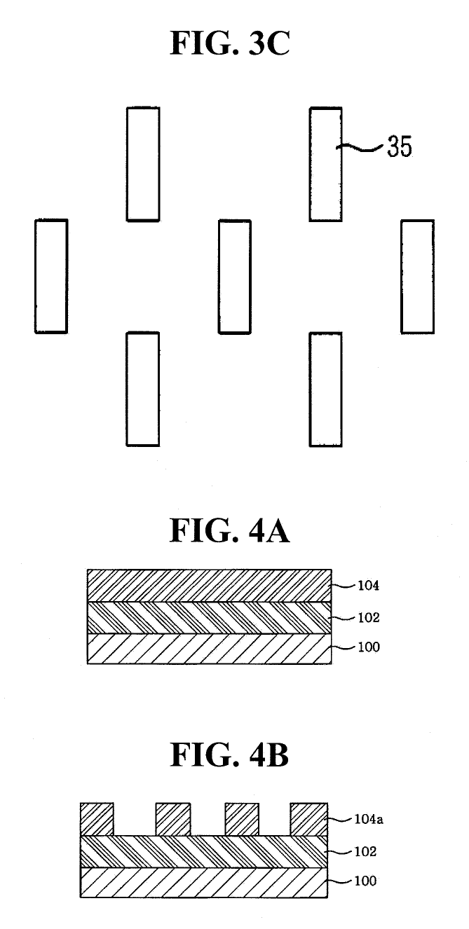

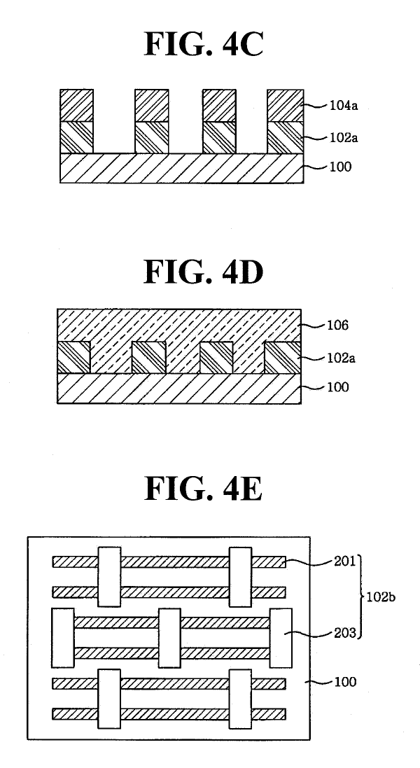

Example FIG. 2 is a view illustrating one example of a line and space pattern, to which a method of forming a pattern in a semiconductor device in accordance with embodiments may be applied.

Example FIGS. 3A, 3B, and 3C are views illustrating one example of a mask pattern for implementing the method in accordance with embodiments.

Example FIGS. 4A to 4E are longitudinal-sectional views illustrating a method of forming a pattern in a semiconductor device in accordance with embodiments.

### DESCRIPTION

The subject matter of embodiments is to form an L/S pattern without a bridge when double patterning is applied to a photolithography process. A first mask pattern is used to form dense lines and a second mask pattern is used to form spaces (parts where ends of the lines are opposite to each other).

A method of forming a pattern in a semiconductor device in accordance with embodiments includes forming a hard mask layer over the upper surface of a semiconductor substrate. A first photosensitive film pattern, corresponding to lines out of a line and space pattern, may be formed using a positive-type photosensitive solution over the upper surface of the hard mask layer to form the lines. A first hard mask pattern may be formed by etching the hard mask layer using the first photosensitive film pattern as a mask. A second photosensitive film pattern, corresponding to inverse shapes of spaces out of the line and space pattern, may be formed using a negative-type photosensitive solution over the upper surface of the resultant structure with the first hard mask pattern to form the spaces. A second hard mask pattern may be formed by etching the first hard mask pattern using the second photosensitive film pattern as a mask. The line and space pattern may be formed by etching the semiconductor substrate using the second hard mask pattern as a mask.

Example FIG. 2 is a view illustrating one example of an L/S pattern, to which the method in accordance with embodiments may be applied. That is, example FIG. 2 is an arrangement plan illustrating a pattern of a gate control (GC) layer in a static RAM (SRAM). As shown in example FIG. 2, the pattern of the GC layer in the SRAM may have a horizontal lattice shape, and thus may have little margin at line end parts 20 due to a fine pitch.

Example FIGS. 3A, 3B, and 3C are views illustrating one example of a mask pattern for implementing the method in accordance with embodiments. Example FIG. 3A illustrates an entire mask pattern 31. Example FIG. 3B illustrates a first mask pattern 33. Example FIG. 3C illustrates a second mask pattern 35.

The entire mask pattern 31 may be formed through double patterning using both the first mask pattern 33 and the second mask pattern 35 shown in example FIGS. 3B and 3C. That is, as shown in example FIGS. 3A to 3C, the entire mask pattern 31 may be configured such that the first mask pattern 33, used to form dense lines disposed horizontally, and the second mask pattern 35, used to form spaces at line end parts disposed vertically, are separately designed.

The reason why the first mask pattern 33 and the second mask pattern 35 are separately designed is because a pattern for the dense lines has a high process margin. If the spaces are separated from the dense lines, ends of the lines are not opposite to each other, and the process margin is increased.

Example FIGS. 4A to 4E are longitudinal-sectional views illustrating a method of forming a pattern in a semiconductor device in accordance with embodiments. As shown in example FIG. 4A, a hard mask layer 102 to form a pattern having a fine pitch may be formed over the upper surface of a semiconductor substrate 100. A first photosensitive film 104, such as a photoresist, may be formed over the upper surface of the hard mask layer 102.

For example, the hard mask layer 102 may be formed by depositing an oxide film or a nitride film through a chemical vapor deposition (CVD) process. The first photosensitive film 104 may be formed by applying a positive-tone photosensitive solution, which reacts to a designated electromagnetic ray, over the mask layer 102 by coating through a spin-coating process.

As shown in example FIG. 4B, a first photosensitive film pattern 104a may be formed by carrying out exposure and development of the first photosensitive film 104. The exposure and development may be performed under the condition that the first mask pattern 33 (with reference to example FIG. 3B) is disposed on (contacts) the first photosensitive film 104. In this manner, the first photosensitive film pattern 104a, corresponding to the dense lines out of the L/S pattern which are disposed horizontally, may be formed.

As shown in example FIG. 4C, a first hard mask pattern 102a may be formed by etching the hard mask layer 102 using the first photosensitive film pattern 104a as a mask until the semiconductor substrate 100 is exposed. As shown in example FIG. 4D, the first photosensitive film pattern 104a may be removed. Then, a second photosensitive film 106, such as a photoresist, may be formed over the upper surface of the entire resultant structure.

For example, the second photosensitive film 106 may be formed by applying a negative-tone photosensitive solution, which may be coated through a spin-coating process. A negative tone photosensitive solution is not developed only when it reacts to a designated ray.

As shown in example FIG. 4E, a second photosensitive film pattern, corresponding to the inverse shape of the second mask pattern 35 (with reference to example FIG. 3C) may be formed by carrying out exposure and development of the second photosensitive film 106. The second photosensitive film may be exposed and developed under the condition that the second mask pattern 35 (with reference to example FIG. 3C) is disposed on (contacts) the second photosensitive film 106. In this manner, the second photosensitive film pattern, corresponding to the inverse shapes of the spaces out of the L/S pattern, which are disposed vertically, may be formed.

Thereafter, a second hard mask pattern 102b may be formed by etching the first hard mask pattern 102a using the second photosensitive film pattern as a mask until the semiconductor substrate 100 is exposed. Here, the second hard mask pattern 102b includes dense lines 201 formed by the first photosensitive film pattern 104a and spaces 203 formed by the second photosensitive film pattern. The second hard mask pattern 102b has a structure corresponding to the entire mask pattern 31 shown in example FIG. 3A. Here, the spaces 203 mean partial regions of the first hard mask pattern 102a, which are removed by etching process using the second photosensitive film pattern.

Finally, when the semiconductor substrate 100 is etched using the second hard mask pattern 102b as a mask, an etched structure having a desired shape may be obtained. For example, a stable gate control (GC) layer without bridges at line end parts out of an L/S pattern in a SRAM may be obtained.

In the method in accordance with embodiments, a first mask pattern to form dense lines and a second mask pattern to form spaces (parts where ends of the lines are opposite to each other) may be used when double patterning is applied to a photolithography process to form a line and space pattern on a semiconductor substrate. Thus, there is no part where ends of lines are opposite to each other, thereby increasing a process margin. Therefore, when the line and space pattern is formed, a fine pattern may be formed while generating no bridge at parts where ends of the lines are opposite to each other.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a hard mask layer over an upper surface of a semiconductor substrate;
forming a first photosensitive film pattern, to form lines out of a line and space pattern, over an upper surface of the hard mask layer;
forming a first hard mask pattern by etching the hard mask layer using the first photosensitive film pattern as a mask;
forming a second photosensitive film pattern, to form spaces out of the line and space pattern, over the upper surface of the resultant structure with the first hard mask pattern;
forming a second hard mask pattern by etching the first hard mask pattern using the second photosensitive film pattern as a mask; and
forming the line and space pattern by etching the semiconductor substrate using the second hard mask pattern as a mask.

2. The method of claim 1, wherein the first photosensitive film pattern and the second photosensitive film pattern respectively use photosensitive solutions of different types.

3. The method of claim 2, wherein the first photosensitive pattern is formed corresponding to the lines.

4. The method of claim 3, wherein the first photosensitive pattern uses a positive-type photosensitive solution.

5. The method of claim 2, wherein the second photosensitive pattern is formed corresponding to inverse shapes of the spaces.

6. The method of claim 5, wherein the second photosensitive pattern uses a negative-type photosensitive solution.

7. The method of claim 1, wherein forming a hard mask layer over an upper surface of a semiconductor substrate includes forming a nitride film through a chemical vapor deposition process.

8. The method of claim 1, wherein forming a hard mask layer over an upper surface of a semiconductor substrate includes forming a oxide film through a chemical vapor deposition process.

9. The method of claim 1, wherein forming a first photosensitive film pattern to form lines includes carrying out an exposure and development process wherein a mask pattern contacts the first photosensitive film.

10. The method of claim 1, wherein forming a second photosensitive film pattern to form spaces includes carrying out an exposure and development process wherein a mask pattern contacts the second photosensitive film.

11. An apparatus configured to:
form a hard mask layer over an upper surface of a semiconductor substrate;
form a first photosensitive film pattern, to form lines out of a line and space pattern, over an upper surface of the hard mask layer;
form a first hard mask pattern by etching the hard mask layer using the first photosensitive film pattern as a mask;
form a second photosensitive film pattern, to form spaces out of the line and space pattern, over the upper surface of the resultant structure with the first hard mask pattern;
form a second hard mask pattern by etching the first hard mask pattern using the second photosensitive film pattern as a mask; and
form the line and space pattern by etching the semiconductor substrate using the second hard mask pattern as a mask.

12. The apparatus of claim 11, wherein the first photosensitive film pattern and the second photosensitive film pattern respectively use photosensitive solutions of different types.

13. The apparatus of claim 12, wherein the first photosensitive pattern is formed corresponding to the lines.

14. The apparatus of claim 13, wherein the first photosensitive pattern uses a positive-type photosensitive solution.

15. The apparatus of claim 12, wherein the second photosensitive pattern is formed corresponding to inverse shapes of the spaces.

16. The apparatus of claim 15, wherein the second photosensitive pattern uses a negative-type photosensitive solution.

17. The apparatus of claim 11 configured to form a hard mask layer over an upper surface of a semiconductor substrate by forming a nitride film through a chemical vapor deposition process.

18. The apparatus of claim 11, configured to form a hard mask layer over an upper surface of a semiconductor substrate by forming a oxide film through a chemical vapor deposition process.

19. The apparatus of claim 11, configured to form a first photosensitive film pattern to form lines by carrying out an exposure and development process wherein a mask pattern contacts the first photosensitive film.

20. The apparatus of claim 11, configured to form a second photosensitive film pattern to form spaces by carrying out an exposure and development process wherein a mask pattern contacts the second photosensitive film.
